(19) United States
(12) Patent Application Publication
(10) Pub. No.: US 2025/0024718 A1
(43) Pub. Date: Jan. 16, 2025

(54) DISPLAY PANEL AND MANUFACTURING METHOD THEREOF, AND DISPLAY DEVICE

(71) Applicants: CHENGDU BOE OPTOELECTRONICS TECHNOLOGY CO., LTD., CHENGDU, SICHUAN (CN); BOE TECHNOLOGY GROUP CO., LTD., BEIJING (CN)

(72) Inventors: Jiandong BAO, Beijing (CN); Yuqun LU, Beijing (CN); Wei WANG, Beijing (CN); Bin LIU, Beijing (CN); Xin ZHOU, Beijing (CN); Shaojie QIN, Beijing (CN)

(73) Assignees: CHENGDU BOE OPTOELECTRONICS TECHNOLOGY CO., LTD., CHENGDU, SICHUAN (CN); BOE TECHNOLOGY GROUP CO., LTD., BEIJING (CN)

(21) Appl. No.: 18/549,041

(22) PCT Filed: Feb. 24, 2023
(86) PCT No.: PCT/CN2023/078112

§ 371 Date: Sep. 5, 2023

(51) Int. Cl. H10K 59/131; H10K 59/124

(52) U.S. Cl. CPC H10K 59/131; H10K 59/124

(57) ABSTRACT

Provided are a display panel and a manufacturing method thereof and a display device. The display panel includes: a base substrate; a first planarization layer; a plurality of sub-pixels, a plurality of anodes of which being located on one side of the first planarization layer away from the base substrate; a pixel defining layer having a plurality of pixel openings; a planarization structure including a plurality of planarization portions, orthographic projection of each of the first group of pixel openings on the base substrate is a first orthographic projection, orthographic projections of an anode and a planarization portion corresponding to each of the first group of pixel openings on the base substrate are a second and a third orthographic projection respectively, and an overlapping portion of the first and second orthographic projections is located within the third orthographic projection.

### CROSS-REFERENCE TO RELATED APPLICATIONS

The present application is a U.S. National Stage Application under 35 U.S.C. § 371 of International Patent Application No. PCT/CN2023/078112, filed on Feb. 24, 2023, the disclosure of which is incorporated by reference herein in its entirety.

### TECHNICAL FIELD

The present disclosure relates to a display panel and a manufacturing method thereof, and a display device.

### BACKGROUND

In the display panel, the service life of the light emitting device (for example, organic light emitting diode (OLED)) can affect the display effect of the display panel.

In order to improve the display effect of the display panel, aging treatment will be performed on the light emitting device in the display panel before shipment of the display panel, so as to consume the stage of rapid performance attenuation of the light emitting device in advance.

### SUMMARY

According to one aspect of the embodiments of the present disclosure, a display panel is provided. The display panel comprises: a base substrate comprising a display region and a peripheral region; a first planarization layer located on one side of the base substrate; a plurality of sub-pixels located at the display region, wherein a plurality of anodes of the plurality of sub-pixels is located on one side of the first planarization layer away from the base substrate; a pixel defining layer located on one side of the first planarization layer and the plurality of anodes away from the base substrate, and having a plurality of pixel openings in one-to-one correspondence with the plurality of anodes, wherein each of the plurality of pixel openings exposes at least a part of an anode corresponding to each of the plurality of pixel openings; and a planarization structure comprising a plurality of planarization portions located at the display region, the plurality of planarization portions being located between the base substrate and the first planarization layer and covered by the first planarization layer, and the plurality of planarization portions being in one-to-one correspondence with a first group of pixel openings, wherein the first group of pixel openings comprise at least a part of the plurality of pixel openings, an orthographic projection of each of the first group of pixel openings on the base substrate is a first orthographic projection, orthographic projections of an anode and a planarization portion which correspond to each of the first group of pixel openings on the base substrate are a second orthographic projection and a third orthographic projection respectively, and an overlapping portion of the first orthographic projection and the second orthographic projection is located within the third orthographic projection.

In some embodiments, the display panel further comprises: a second planarization layer located between the first planarization layer and the base substrate, wherein the plurality of planarization portions is located between the first planarization layer and the second planarization layer; wherein each of the plurality of sub-pixels further comprises: a pixel driving circuit comprising a driving transistor, the driving transistor comprising a gate, a first electrode and a second electrode, wherein the first electrode and the second electrode are covered by the second planarization layer, and a metal portion located between the first planarization layer and the second planarization layer, wherein the metal portion is connected to the anode via a first via hole penetrating through the first planarization layer and connected to the first electrode via a second via hole penetrating through the second planarization layer.

In some embodiments, the plurality of planarization portions is located in a same layer as the metal portion.

In some embodiments, the display panel further comprises a plurality of data lines configured to provide a data signal to the plurality of sub-pixels, each of the plurality of data lines comprising: a first data portion located at the display region and located in a same layer as the first electrode; and a second data portion located at the peripheral region, connected to the first data portion and located in a same layer as the metal portion.

In some embodiments, the display panel further comprises: a plurality of second power lines configured to provide a second power signal to the plurality of sub-pixels, wherein a voltage of the second power signal is greater than a voltage of a first power signal provided to a cathode of the plurality of sub-pixels, and the plurality of second power lines is located in a same layer as the first electrode.

In some embodiments, the display panel further comprises: a plurality of signal lines configured to provide a signal to the plurality of sub-pixels, wherein at least one planarization portion of the plurality of planarization portions is arranged in a same layer as one of the plurality of signal lines and connected to the one of the plurality of signal lines.

In some embodiments, the plurality of signal lines extends along a first direction, and a minimum length of the at least one planarization portion in a second direction is greater than a maximum length of the one of the plurality of signal lines in the second direction, wherein the first direction is perpendicular to the second direction.

In some embodiments, the plurality of signal lines comprises: a data line configured to provide a data signal to the plurality of sub-pixels; or a second power line configured to provide a second power signal to the plurality of sub-pixels, wherein a voltage of the second power signal is greater than a voltage of the first power signal.

In some embodiments, the first power line is located in a same layer as the metal portion.

In some embodiments, an area of the overlapping portion of the first orthogonal projection and the second orthogonal projection is smaller than an area of the third orthogonal projection.

In some embodiments, the display panel further comprises: a first power line located at the peripheral region and configured to provide a first power signal to a cathode of the plurality of sub-pixels; and a conductive structure comprising at least one conductive portion located at the display region, wherein the at least one conductive portion is configured such that a part of current flowing from the plurality of anodes to the first power line via the cathode flows back to the first power line via the at least one conductive portion.

According to another aspect of the embodiments of the present disclosure, provided is a display panel, comprising: a base substrate comprising a display region and a peripheral region; a plurality of sub-pixels located at the display region; a first power line located at the peripheral region and configured to provide a first power signal to a cathode of the plurality of sub-pixels; and a conductive structure comprising at least one conductive portion located at the display region, wherein the at least one conductive portion is configured such that a part of current flowing from a plurality of anodes of the plurality of sub-pixels to the first power line via the cathode flows back to the first power line via the at least one conductive portion.

In some embodiments, the peripheral region comprises a first peripheral region and a second peripheral region arranged oppositely, and a third peripheral region and a fourth peripheral region arranged oppositely, wherein the third peripheral region and the fourth peripheral region are both adjacent to the first peripheral region and the second peripheral region; the first power line comprises: a first power portion located at the first peripheral region; a second power portion located at the second peripheral region; a third power portion located at the third peripheral region and connected between the first power portion and the second power portion; and a fourth power portion located at the fourth peripheral region and comprising a first portion and a second portion, wherein the first portion is connected between the first power portion and a first pad, and the second portion is connected between the third power portion and a second pad; and the at least one conductive portion is connected to the first power portion via a first connection line and connected to the second power portion via a second connection line.

In some embodiments, the at least one conductive portion comprises a plurality of conductive portions connected to each other.

In some embodiments, the plurality of conductive portions comprises a plurality of groups of conductive portions, wherein each group of conductive portions are arranged sequentially along a direction from the first power portion to the second power portion, adjacent conductive portions in each group of conductive portions are connected to each other via a third connection line, a first conductive portion in each group of conductive portions that is closest to the first power portion is connected to the first power portion via the first connection line, and a second conductive portion in each group of conductive portions that is closest to the second power portion is connected to the second power line via the second connection line.

In some embodiments, two adjacent groups of conductive portions of the plurality groups of conductive portions comprise a first group of conductive portions and a second group of conductive portions, and at least one conductive portion of the first group of conductive portions is connected to one conductive portion of the second group of conductive portions via a fourth connection line.

In some embodiments, different conductive portions in the first group of conductive portions are connected to different conductive portions in the second group of conductive portions via different fourth connection lines.

In some embodiments, the display panel further comprises: a first trace located at the first peripheral region, connected to the first power portion, and located in a different layer from the first power portion; and a second trace located at the second peripheral region, connected to the second power portion, and located in a different layer from the second power portion, wherein the at least one conductive portion, the first power portion and the second power portion are located in a same layer, and the at least one conductive portion is connected to the first trace via the first connection line and connected to the second trace via the second connection line.

In some embodiments, the first trace layer is in contact with the first power portion, and the second trace layer is in contact with the second power portion.

In some embodiments, the at least one conductive portion comprises a plurality of conductive portions connected to each other, and each of the plurality of conductive portions is reused as one of the plurality of planarization portions.

In some embodiments, a material of the at least one conductive portion is light shielding material, each of the at least one conductive portion is located between a pixel driving circuit of a corresponding sub-pixel of the plurality of sub-pixels and the base substrate, and an orthographic projection of each of the at least one conductive portion on the base substrate at least partially overlaps with an orthographic projection of the pixel driving circuit of the corresponding sub-pixel on the base substrate.

According to still another aspect of the embodiments of the present disclosure, provided is a display panel, comprising: a base substrate comprising a display region and a peripheral region; a plurality of sub-pixels located at the display region; a first power line located at the peripheral region and configured to provide a first power signal to a cathode of the plurality of sub-pixels; and a conductive structure comprising at least one conductive portion located at the display region, wherein the at least one conductive portion is connected to the first power line via a first connection line and connected to the first power line via a second connection line.

According to yet still another aspect of the embodiments of the present disclosure, provided is a display device, comprising the display panel according to any of the above embodiments.

According to further aspect of the embodiments of the present disclosure, provided is a manufacturing method of a display panel, comprising: providing a base substrate, wherein the base substrate comprises a display region and a peripheral region; forming a first planarization layer on one side of the base substrate; forming a plurality of anodes of a plurality of sub-pixels located at the display region on one side of the first planarization layer away from the base substrate; forming a pixel defining layer on one side of the first planarization layer and the plurality of anodes away from the base substrate, wherein the pixel defining layer has a plurality of pixel openings in one-to-one correspondence with the plurality of anodes, and each of the plurality of pixel openings exposes at least a part of an anode corresponding to each of the plurality of pixel openings; and forming a planarization structure, the planarization structure comprising a plurality of planarization portions located at the display region, the plurality of planarization portions being located between the base substrate and the first planarization layer and covered by the first planarization layer, and the plurality of planarization portions being in one-to-one correspondence with a first group of pixel openings, wherein the first group of pixel openings comprise at least a part of the plurality of pixel openings, an orthographic projection of each of the first group of pixel openings on the base substrate is a first orthographic projection, orthographic projections of an anode and a planarization portion which correspond to each of the first group of pixel openings on the base substrate are a second orthographic projection and a third orthographic projection respectively, and an overlapping portion of the first orthographic projection and the second orthographic projection is located within the third orthographic projection.

According to further aspect of the embodiments of the present disclosure, provided is a manufacturing method of a display panel, comprising: providing a base substrate, wherein the base substrate comprises a display region and a peripheral region; forming a plurality of sub-pixels located at the display region; forming a first power line located at the peripheral region and configured to provide a first power signal to a cathode of the plurality of sub-pixels; and forming a conductive structure comprising at least one conductive portion located at the display region, wherein the at least one conductive portion is configured such that a part of current flowing from the plurality of anodes to the first power line via the cathode flows back to the first power line via the at least one conductive portion.

### BRIEF DESCRIPTION OF THE ACCOMPANYING DRAWINGS

The accompanying drawings which constitute part of this specification, illustrate the embodiments of the present disclosure, and together with this specification, serve to explain the principles of the present disclosure.

The present disclosure may be more explicitly understood from the following detailed description with reference to the accompanying drawings, in which:

FIG. 1A is a schematic top view showing a display panel according to some embodiments of the present disclosure;

FIG. 1B is a schematic cross-sectional view showing a display region of a display panel according to some embodiments of the present disclosure;

FIG. 1C is a schematic cross-sectional view showing a peripheral region of a display panel according to some embodiments of the present disclosure;

FIGS. 2A-2C are schematic top views showing a display panel according to some embodiments of the present disclosure;

FIG. 3A is a schematic top view showing a display panel according to other embodiments of the present disclosure;

FIG. 3B is a schematic cross-sectional view showing a display region according to other embodiments of the present disclosure;

FIG. 4 is a schematic top view showing a display panel according to further embodiments of the present disclosure;

FIG. 5 is a schematic top view showing a display panel according to still further embodiments of the present disclosure;

FIGS. 6A-6D are schematic views showing the distribution of a plurality of conductive portions according to some embodiments of the present disclosure;

FIG. 7A is a schematic top view showing a display panel according to further embodiments of the present disclosure;

FIG. 7B is a schematic top view showing a display region according to still other embodiments of the present disclosure;

FIG. 8A is a schematic top view showing a display panel according to still other embodiments of the present disclosure;

FIG. 8B is a schematic top view showing a display region according to still other embodiments of the present disclosure;

FIG. 9 is a flowchart showing a manufacturing method of a display panel according to some embodiments of the present disclosure;

FIG. 10 is a flowchart showing a manufacturing method of a display panel according to other embodiments of the present disclosure.

It should be appreciated that, the same or similar reference numerals refer to the same or similar components.

### DETAILED DESCRIPTION

Various exemplary embodiments of the present disclosure will now be described in detail with reference to the accompanying drawings. The following description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “have” or variants thereof means that the element before the word covers the element(s) listed after the word without excluding the possibility of also covering other elements. The terms “up”, “down”, or the like are used only to represent a relative positional relationship, and the relative positional relationship may be changed correspondingly if the absolute position of the described object changes.

In the present disclosure, when it is described that a specific component is disposed between a first component and a second component, there may be an intervening component between the specific component and the first component or between the specific component and the second component. When it is described that a specific part is connected to other parts, the specific part may be directly connected to the other parts without an intervening part, or not directly connected to the other parts with an intervening part.

Unless otherwise defined, all terms (including technical and scientific terms) used herein have the same meanings as the meanings commonly understood by one of ordinary skill in the art to which the present disclosure belongs. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

The display panel in the related art has a poor display effect. The inventors have carried out studies and analysis on this.

The inventors have noticed that, on the one hand, after aging treatment, the display panel has a low yield. After analysis, it has been found that the current flowing through the light emitting device during the process of aging treatment is greater than the current flowing through the light emitting device during the normal display process of the display panel, for example, the former is 3 to 5 times the latter. The current flowing through each light emitting device in the display panel will eventually flow out through a power line connected to the cathode of the light emitting device. It is likely to burn the power line during the process of aging the light emitting device, thereby reducing the yield of the display panel.

The inventors also have noticed that, on the other hand, the display panel has a color cast problem during the display process. After analysis, it has been found that the signal lines (for example, the data lines) below anodes of different light emitting devices are at different positions relative to the anodes, which results in different flatness of the anodes of the light emitting devices, and further causes the color cast problem of the display panel during the display process.

In view showing this, the embodiments of the present disclosure provide the following technical solutions to improve the display effect of the display panel.

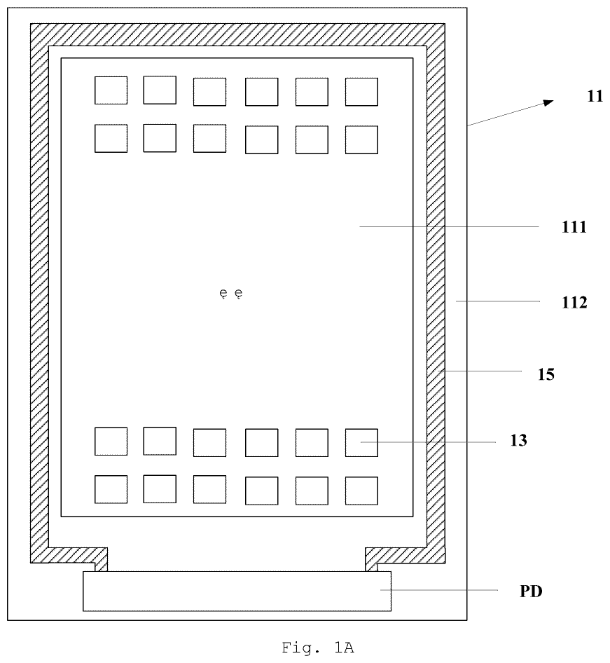

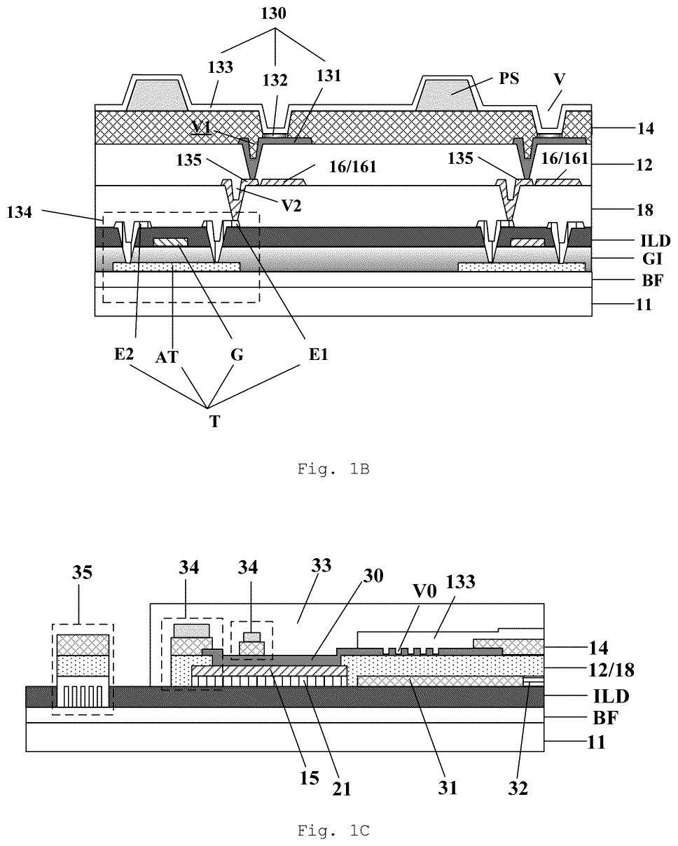

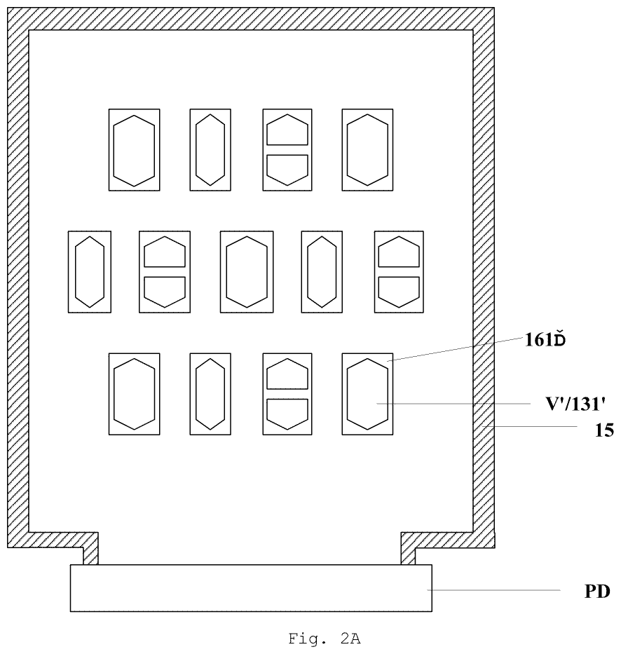

FIG. 1A is a schematic top view showing a display panel according to some embodiments of the present disclosure. FIG. 1B is a schematic cross-sectional view showing a display region of a display panel according to some embodiments of the present disclosure. FIG. 1C is a schematic cross-sectional view showing a peripheral region of a display panel according to some embodiments of the present disclosure.

It is to be noted that, in order to show the structure of the display panel more explicitly, FIGS. 1A to 1C highlight some members of the display panel respectively.

Hereinafter, some members of the display panel according to some embodiments of the present disclosure will be described in conjunction with FIGS. 1A to 1C.

In some embodiments, as shown in FIGS. 1A to 1C, the display panel comprises a base substrate 11, a first planarization layer 12, a plurality of sub-pixels 13, a pixel defining layer 14 and a planarization structure 16.

Referring to FIG. 1A, the base substrate 11 comprises a display region 111 and a peripheral region 112. The peripheral region 112 may be arranged around the display region 111. In some embodiments, the display panel further comprises a buffer layer BF located on the surface of the base substrate 11. FIG. 1A also shows a pad region PD located at the peripheral region 112. The pad region PD may comprise a pad connected to a signal line. In some embodiments, the base substrate 11 may comprise a flexible base substrate, for example, a polyimide (PI) base substrate or the like. It is to be noted that, FIG. 1A which only schematically shows the shape of the display region 111 and the shape of the peripheral region 112 to be rectangular and does not serve as a limitation to the present disclosure. For example, in some embodiments, the corners of the display region 111 and the corners of the peripheral region 112 may have radians, for example, circular arcs.

The plurality of sub-pixels 13 is located at the display region 111. For example, the plurality of sub-pixels 13 may comprise a red sub-pixel, a green sub-pixel, and a blue sub-pixel.

Referring to FIG. 1B, each sub-pixel 13 comprises a light emitting device 130 (for example, OLED). The light emitting device 130 comprises an anode 131, a functional layer 132 and a cathode 133. Here, the functional layer 132 is located between the anode 131 and the cathode 133. The functional layer 132 at least comprises a light emitting layer, for example, an organic light emitting layer. In some embodiments, the functional layer 132 may further comprise one or more of an electron transport layer, an electron injection layer, a hole transport layer and a hole injection layer. In some embodiments, the plurality of sub-pixels 13 may share a cathode 133.

The first planarization layer 12 is located on one side of the base substrate 11. For example, the first planarization layer 12 is located on the upper side of the base substrate 11. A plurality of anodes 131 of the plurality of sub-pixels 13 is located on one side of the first planarization layer 12 away from the base substrate 11.

The pixel defining layer 14 is located on one side of the first planarization layer 12 and the plurality of anodes 131 away from the base substrate 11. The pixel defining layer 14 comprises a plurality of pixel openings V in one-to-one correspondence with the plurality of anodes 131, and each pixel opening V exposes at least a part of a corresponding anode 131. The functional layer 132 and the cathode 133 of the light emitting device 130 in each sub-pixel 13 are at least partially located in a corresponding pixel opening V. In some embodiments, the display panel further comprises a support PS located on one side of the pixel defining layer 14 away from the base substrate 11. In some embodiments, the material of at least one of the buffer layer BF, the first planarization layer 12, the pixel defining layer 14 or the support PS may comprise an organic insulating material such as polyimide or resin material, or comprise an inorganic insulating material such as silicon oxide, silicon nitride, or silicon oxynitride, etc.

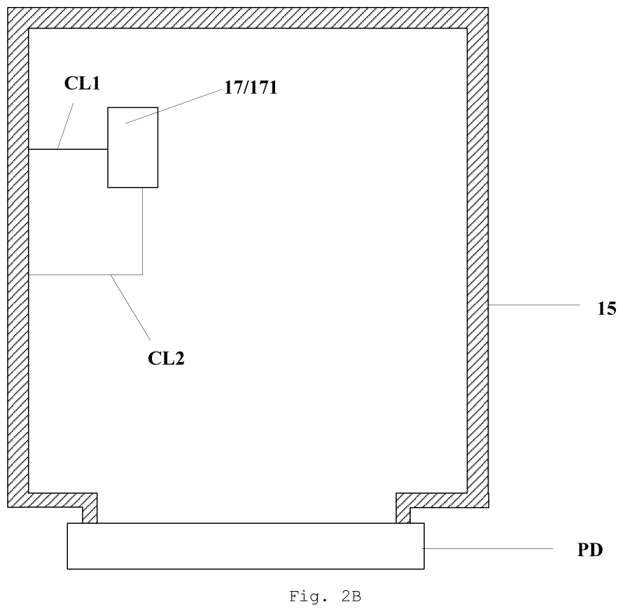

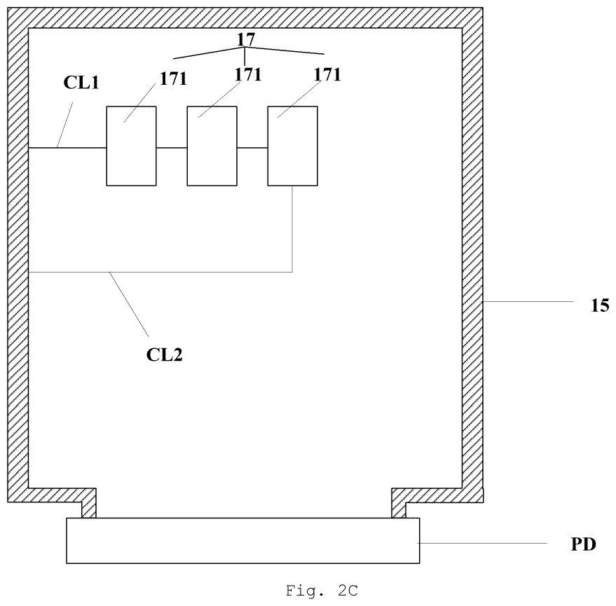

FIGS. 2A-2C are schematic top views showing a display panel according to some embodiments of the present disclosure.

First, the planarization structure 16 will be introduced in conjunction with FIGS. 1B and 2A.

Referring to FIG. 1B, the planarization structure 16 comprises a plurality of planarization portions 161 located at the display region 111. The plurality of planarization portions 161 is located between the base substrate 11 and the first planarization layer 12, and covered by the first planarization layer 12. As some implementations, the planarization portion 161 is conductive. As other implementations, the planarization portion 161 is not conductive.

The plurality of planarization portions 161 is in one-to-one correspondence with a first group of pixel openings V, and the first group of pixel openings V comprise at least a part of the plurality of pixel openings V in the pixel defining layer 14. In some embodiments, the first group of pixel openings V comprise some pixel openings V of the plurality of pixel openings V in the pixel defining layer 14. In other embodiments, the first group of pixel openings V comprises a pixel opening V of the pixel defining layer 14 corresponding to the anode 131 of each sub-pixel 13 in the display panel.

Referring to FIG. 2A, the orthographic projection of each pixel opening V among the first group of pixel openings V on the base substrate 11 is a first orthographic projection V′, and the orthographic projections of an anode 131 and a planarization portion 161 corresponding to each pixel opening V among the first group of pixel openings V on the base substrate 11 are a second orthographic projection 131′ and a third orthographic projection 161′ respectively. The overlapping portion of the first orthographic projection V′ and the second orthographic projection 131′ is located within the third orthographic projection 161′. The plurality of planarization portions 161 are provided to help to raise the flatness of the corresponding anode 131, thereby alleviating the color cast problem of the display panel.

In some embodiments, the area of the overlapping portion of the first orthogonal projection V′ and the second orthogonal projection 131′ is smaller than the area of the third orthogonal projection 161′. In this way, the flatness of the anodes 131 corresponding to the plurality of planarization portions 161 is further raised, thereby further alleviating the color cast problem of the display panel.

In other embodiments, as shown in FIGS. 1A, 1C, 2B and 2C, the display panel comprises a base substrate 11, a plurality of sub-pixels 13, a first power line 15 and a conductive structure 17. For the base substrate 11 and the plurality of sub-pixels 13, reference can be made to the previous description, and thus will not be described in detail here.

First, the first power line 15 will be introduced in conjunction with FIGS. 1A and 1C.

The first power line 15 is located at the peripheral region 112 and configured to provide a first power signal to the cathode 133 of the plurality of sub-pixels 13. In some embodiments, referring to FIG. 1C, the first power line 15 is connected to the cathode 133 via a connection layer 30. For example, the connection layer 30 is located between the cathode 133 and the first power line 15, and in contact with the cathode 133 and the first power line 15 respectively. As some implementations, the connection layer 30 has a plurality of openings V0, and the cathode 133 is partially located in the plurality of openings V0 of the connection layer 30, so that the reliability of the connection between the cathode 133 and the connection layer 30 is enhanced.

In some embodiments, the connection layer 30 and the anode 131 of the sub-pixel 13 are located in a same layer. For example, the connection layer 30 and the anode 131 both comprise a laminate which comprises indium tin oxide (ITO)/silver (Ag)/ITO, for example. It is to be noted that, in the embodiments of the present disclosure, when it is described that a plurality of members is located in a same layer, it means that the plurality of members is formed by patterning a same material layer. Therefore, the materials of the plurality of members located in a same layer are the same.

Next, the conductive structure 17 will be introduced in conjunction with FIGS. 2B and 2C.

Referring to FIGS. 2B and 2C, the conductive structure 17 comprises at least one conductive portion 171 located at the display region 111. FIG. 2B shows a case where the conductive structure 17 comprises only one conductive portion 171; and FIG. 2C shows a case where the conductive structure 17 comprises a plurality of conductive portions 171.

The at least one conductive portion 171 is configured such that a part of the current flowing from the plurality of anodes 131 of the plurality of sub-pixels 13 to the first power line 15 via the cathode 133 flows back to the first power line 15 via the at least one conductive portion 171. In other words, a part of the current flowing from the plurality of anodes 131 to the first power line 15 via the cathode 133 can be shunted to the conductive portion 171. In this way, at least during the period when the part of the current that is shunted does not flow back to the first power line 15, the current flowing from the first power line 15 to the pad region PD is reduced, thereby reducing the possibility that the first power line 15 is burned during the aging process and improving the yield of the display panel.

In some embodiments, the display panel comprises at least one of the planarization structure 16 or the conductive structure 17. In this way, at least one of the color cast problem of the display panel or the problem that the first power line 15 is burned during the aging process is alleviated, thereby improving the display effect of the display panel.

In some embodiments, the display panel comprises the base substrate 11, the first planarization layer 12, the plurality of sub-pixels 13, the pixel defining layer 14, the first power line 15, the planarization structure 16 and the conductive structure 17. In this way, the color cast problem of the display panel or the problem that the first power line 15 is burned during the aging process are alleviated, thereby further improving the display effect of the display panel.

Next, other members in the display panel will be described in conjunction with FIG. 1C.

In some embodiments, referring to FIG. 1C, the display panel further comprises a driving circuit 31 located at the peripheral region 112. For example, the driving circuit 31 comprises, for example, at least one of a gate driving circuit or a light emission control driving circuit.

In other embodiments, referring to FIG. 1C, the display panel further comprises an initialization bus 32 located at the peripheral region 112. The initialization bus 32 is connected to a plurality of initialization lines located at the display region 111 to provide an initialization signal to the plurality of sub-pixels 13. For example, the driving circuit 31 is located between the initialization bus 32 and the first power line 15. As some implementations, the initialization bus 32 is located in a same layer as certain member located at the display region 111 (for example, a first electrode E1 mentioned below).

In other embodiments, referring to FIG. 1C, the display panel further comprises an encapsulation layer 33. The encapsulation layer 33 may comprise a thin film encapsulation layer. In some embodiments, the encapsulation layer 33 may comprise a first inorganic layer, a second inorganic layer, and an organic layer located between the first inorganic layer and the second inorganic layer.

In still other embodiments, referring to FIG. 1C, the display panel further comprises one or more dams 34 located at the peripheral region 112. Each dam 34 is arranged around the display region 111 to block the flow of the organic layer in the encapsulation layer 33 during the forming process of the organic layer. For example, the dam 34 comprises a plurality of layers, wherein at least one of the plurality of layers may be located in a same layer as certain member located at the display region 111.

In still some embodiments, referring to FIG. 1C, the display panel further comprises a barrier structure 35 located at the peripheral region 112, to reduce the adverse effect of water vapor and oxygen on the sub-pixels 13 located at the display region 111. For example, the barrier structure 35 comprises a plurality of layers, at least one of which may be located in a same layer as certain member located at the display region 111.

In order to more effectively alleviate the color cast problem of the display panel, the embodiments of the present disclosure also provide the following technical solutions, which will be described below in conjunction with different embodiments.

In some embodiments, referring to FIG. 1B, the display panel further comprises a second planarization layer 18. The second planarization layer 18 is located between the first planarization layer 12 and the base substrate 11, and the plurality of planarization portions 161 is located between the first planarization layer 12 and the second planarization layer 18.

Each of the plurality of sub-pixels 13 further comprises a pixel driving circuit 134 that drives the light emitting device 130. The pixel driving circuit 134 comprises a driving transistor T connected to the anode 131 of the light emitting device 130. The driving transistor T comprises a gate G, a first electrode E1 and a second electrode E2. The first electrode E1 and the second electrode E2 are covered by the second planarization layer 18. For example, the first electrode E1 and the second electrode E2 are connected to the active layer AT of the driving transistor T via a via hole penetrating through a first insulating layer ILD and a second insulating layer GI respectively. For example, the gate G is located on one side of the second insulating layer GI away from the active layer AT and covered by the first insulating layer ILD; and the first electrode E1 and the second electrode E2 are located between the second insulating layer ILD and the second planarization layer 18. In some embodiments, the display panel further comprises a buffer layer BF located between the active layer AT and the base substrate 11.

It should be understood that, the pixel driving circuit 134 may further comprise other transistors and capacitors in addition to the driving transistor T. For example, the pixel driving circuit 134 may comprise two transistors and one capacitor (2T1C). For another example, the pixel driving circuit 134 may comprise six transistors and one capacitor (6T1C). For still another example, the pixel driving circuit 134 may comprise seven transistors and one capacitor (7T1C).

The metal portion 135 is located between the first planarization layer 12 and the second planarization layer 18. In addition, the metal portion 135 is connected to the anode 131 via a first via hole V1 penetrating through the first planarization layer 12 and connected to the first electrode E1 via a second via hole V2 penetrating through the second planarization layer 18.

In the above embodiments, the display panel comprises the first planarization layer 12 and the second planarization layer 18, and the first electrode E1 of the driving transistor T is connected to the anode 131 via the second via hole V2, the metal portion 135 and the first via hole V1 sequentially. The plurality of planarization portions 161 is located between the first planarization layer 12 and the second planarization layer 18. In this way, compared with the planarization portion 161 arranged in other positions (for example, on one side of the second planarization layer 18 away from the first planarization layer 12), the planarization portion 161 is more proximate to the anode 131, and the flatness of the anode 131 is more effectively raised, thereby effectively alleviating the color cast problem of the display panel.

In some embodiments, referring to FIG. 1B, the plurality of planarization portions 161 is located in a same layer as the metal portion 135. In this way, the plurality of planarization portions 161 and the metal portion 135 may be formed by a same patterning process, which is helpful to simplify the manufacturing process of the display panel and save the cost.

In some embodiments, the first power line 15 shown in FIG. 1C is located in a same layer as the metal portion 135 shown in FIG. 1B. In this way, the first power line 15 is more proximate to the cathode 133, which is more convenient for the cathode 133 to be connected to the first power line 15 via the connection layer 30.

The inventors also have noticed that, in a case where the display panel comprises a plurality of planarization portions 161, the plurality of planarization portions 161 might affect other signal lines. Accordingly, the embodiments of the present disclosure also provide the following technical solutions.

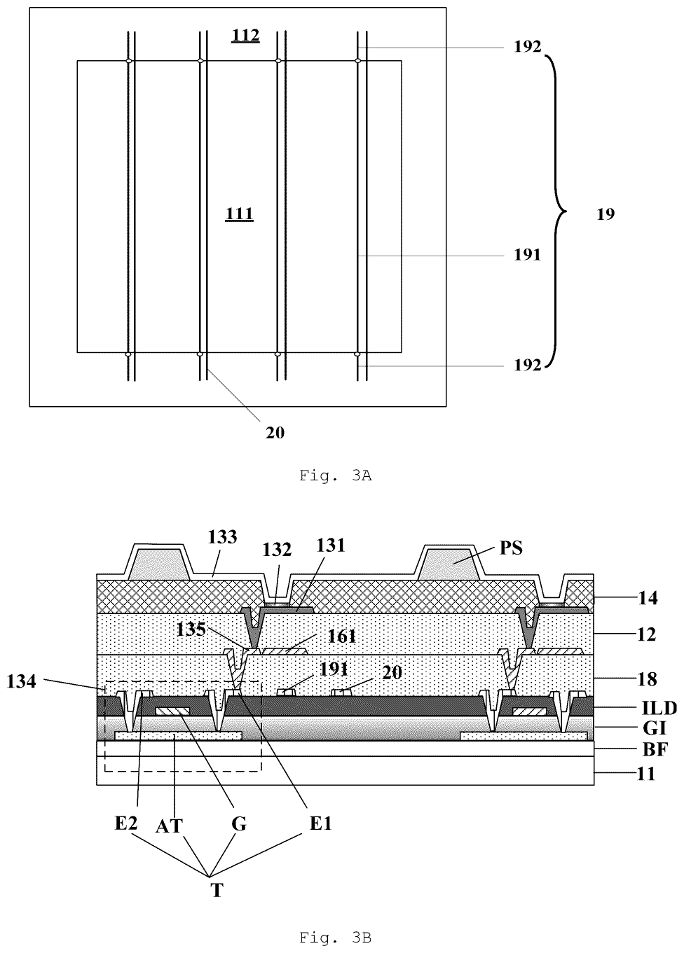

FIG. 3A is a schematic top view showing a display panel according to other embodiments of the present disclosure. FIG. 3B is a schematic cross-sectional view showing a display region according to other embodiments of the present disclosure.

In some embodiments, referring to FIG. 3A, the display panel further comprises a plurality of data lines 19. The plurality of data lines 19 is configured to provide a data signal to the plurality of sub-pixels 13. For example, each data line 19 is configured to provide a data signal to a corresponding column of sub-pixels 13.

Each of the plurality of data lines 19 comprises a first data portion 191 and a second data portion 192 connected to the first data portion 191. The first data portion 191 is located at the display region 111, and located in a same layer as the first electrode E1 in the driving transistor T, as shown in FIG. 3B. The second data portion 192 is located at the peripheral region 112, and located in a same layer as the metal portion 135. For example, the first data portion 191 is connected to the second data portion 192 via a via hole.

In the above embodiments, in the case where the plurality of planarization portions 161 located at the display region 111 is located in a same layer as the metal portion 135, a portion of the data line 19 located at the display region 111 (i.e., the first data portion 191) is located in a same layer as the first electrode E1 in the driving transistor T, and a portion of the data line 19 located at the peripheral region 112 (i.e., the second data portion 192) is located in a same layer as the metal portion 135. In this way, the portion of the data line 19 located at the display region 111 is located in a different layer from the planarization portion 161, which reduces the influence of the planarization portion 161 on the data line 19 and further improves the effect of the display panel.

In other embodiments, referring to FIG. 3A, the display panel further comprises a plurality of second power lines 20 configured to provide a second power signal to the plurality of sub-pixels 13. For example, each second power line 20 is configured to provide a second power signal to a corresponding column of sub-pixels 13. Here, the voltage of the second power signal is greater than the voltage of a first power signal provided to the cathode 133 of the plurality of sub-pixels 13.

Referring to FIG. 3B, the plurality of second power lines 20 is located in a same layer as the first electrode E1 of the driving transistor. In this way, the second power line 20 is located in a different layer from the planarization portion 161, which reduces the influence of the planarization portion 161 on the second power line 20 and further improves the effect of the display panel.

In still some embodiments, the first data portion 191 of the data line 19 located at the display region 111 is located in a different layer from the planarization portion 161, and the second power line 20 is located in a different layer from the planarization portion 161. In this way, the influence of the planarization portion 161 on the data line 19 and the influence of the planarization portion 161 on the second power line 20 are both reduced, thereby further improving the effect of the display panel.

In a case where the display panel comprises a plurality of planarization portions 161, in order to simplify the manufacturing process of the display panel, the planarization portion 161 may be integrally provided with certain signal line. Description will be made below in conjunction with different embodiments.

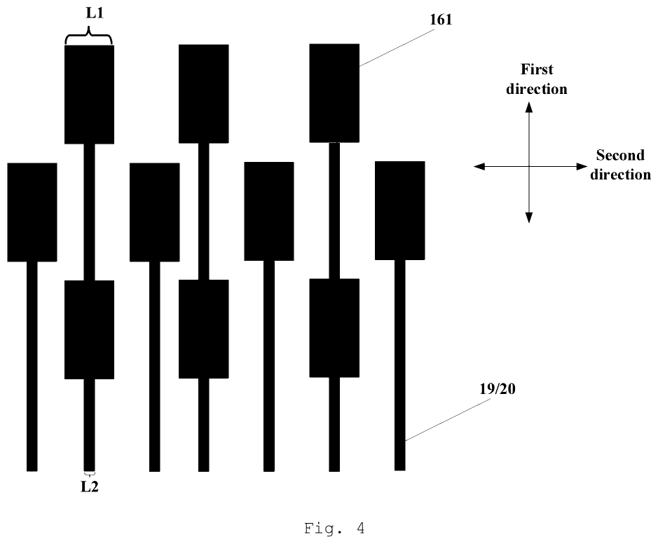

FIG. 4 is a schematic top view showing a display panel according to further embodiments of the present disclosure.

In some embodiments, the display panel further comprises a plurality of signal lines, for example, a data line 19 or a second power line 20 shown in FIG. 4. The plurality of signal lines is configured to provide a signal to the plurality of sub-pixels 13, for example, a data signal or a second power signal.

In this case, at least one planarization portion 161 of the plurality of planarization portions 161 is arranged in a same layer as one of the plurality of signal lines and connected to the one of the plurality of signal lines. In other words, at least one planarization portion 161 is integrally provided with a corresponding signal line.

In some embodiments, each planarization portion 161 of the plurality of planarization portions 161 is arranged in a same layer as a corresponding signal line of the plurality of signal lines and connected to the corresponding signal line of the plurality of signal lines. It should be understood that different planarization portions 161 correspond to different signal lines. In this way, each planarization portion 161 is integrally provided with a corresponding signal line without additionally introducing other layers, which is helpful to simplify the manufacturing process of the display panel.

As some implementations, the plurality of signal lines comprises a data line 19, for example, a plurality of data lines 19. In this case, for example, each planarization portion 161 of the plurality of planarization portions 161 is arranged in a same layer as a corresponding data line of the plurality of data lines 19 and connected to the corresponding data line of the plurality of data lines 19. For example, the data line 19 is located in a same layer as the metal portion 135.

As other implementations, the plurality of signal lines comprises a second power line 20, for example, a plurality of second power lines 20. In this case, for example, each planarization portion 161 of the plurality of planarization portions 161 is arranged in a same layer as a corresponding second power line 20 of the plurality of second power lines 20 and connected to the corresponding second power line 20 of the plurality of second power lines 20. For example, the second power line 20 is located in a same layer as the metal portion 135.

In some embodiments, referring to FIG. 4, a plurality of signal lines (for example, the data line 19 or the second power line 20) extend along a first direction, and the minimum length Li of at least one planarization portion 161 of the plurality of planarization portions 161 in a second direction perpendicular to the first direction is greater than the maximum length of a signal line which is arranged in a same layer as the at least one planarization portion 161 and connected to the at least one planarization portion 161 in the second direction. It can be understood that the data line 19 or the second power line 20 shown in FIG. 4 can be formed by patterning a same material layer once with a mask.

Next, the technical solutions of further alleviating the problem that the first power line 15 is burned during the aging process will be introduced in conjunction with some embodiments.

FIG. 5 is a schematic top view showing a display panel according to still further embodiments of the present disclosure.

As shown in FIG. 5, the peripheral region 112 comprises a first peripheral region 112A and a second peripheral region 112B arranged oppositely, and a third peripheral region 112C and a fourth peripheral region 112D arranged oppositely. The third peripheral region 112C and the fourth peripheral region 112D are both adjacent to the first peripheral region 112A and the second peripheral region 112B. In FIG. 5, different peripheral regions are spaced apart by a dotted line. It should be understood that the position of the dotted line in FIG. 5 is only schematic.

The first power line 15 comprises a first power portion 151, a second power portion 152, a third power portion 153 and a fourth power portion. The first power portion 151 is located at the first peripheral region 112A; the second power portion 152 is located at the second peripheral region 112B; the third power portion 153 is located at the third peripheral region 112C and connected between the first power portion 151 and the second power portion 152; and the fourth power portion 154 is located at the fourth peripheral region 112D. The fourth power portion 154 comprises a first portion 154A and a second portion 154B. The first portion 154A is connected between the first power portion 151 and a first pad P1 in the pad region PD, and the second portion 154B is connected between the third power portion 153 and the second pad P2 in the pad region PD.

At least one conductive portion 171 is connected to the first power portion 151 via a first connection line CL1, and connected to the second power portion 152 via a second connection line CL2.

In the above embodiments, the conductive portion 171 is connected to the first power portion 151 and the second power portion 152 arranged oppositely via different connection lines respectively. In this way, a part of the current flowing from the plurality of anodes 131 to the first power line 15 via the cathode 133 can flow from one of the first power portion 151 and the second power portion 152 to the other of the first power portion 151 and the second power portion 152 via the conductive portion 171, which can shunt the current in the first power line 15 more effectively, thereby further reducing the possibility that the first power line 15 is burned during the aging process, and further improving the yield of the display panel.

In some embodiments, the display panel comprises a plurality of conductive portions 171 connected to each other. In this way, a part of the current flowing from the plurality of anodes 131 to the first power line 15 via the cathode 133 can flow from one of the first power portion 151 and the second power portion 152 to the other of the first power portion 151 and the second power portion 152 via the plurality of conductive portions 171, thereby further reducing the possibility that the first power line 15 is burned during the aging process, and further improving the yield of the display panel.

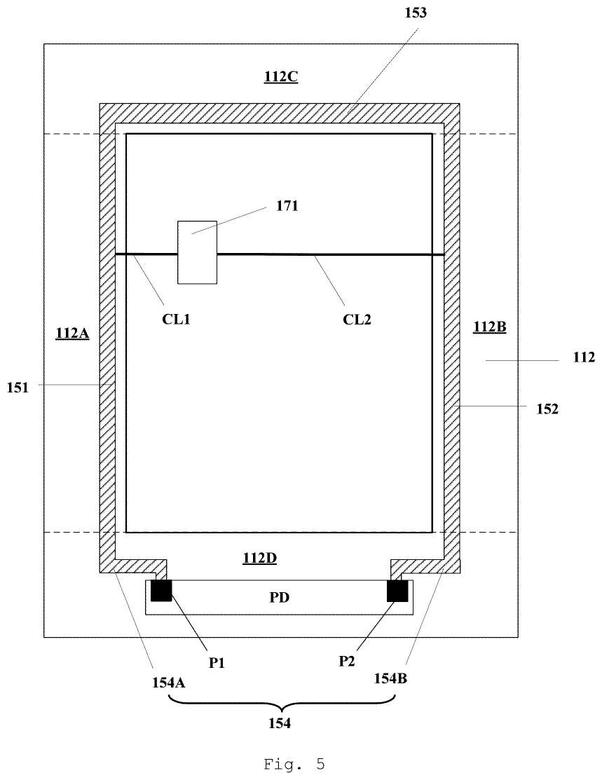

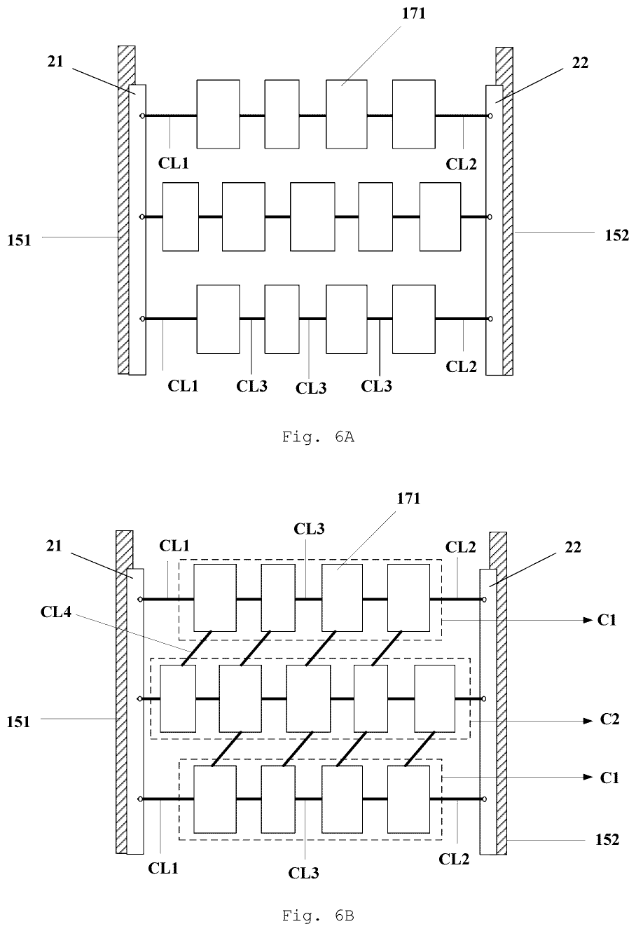

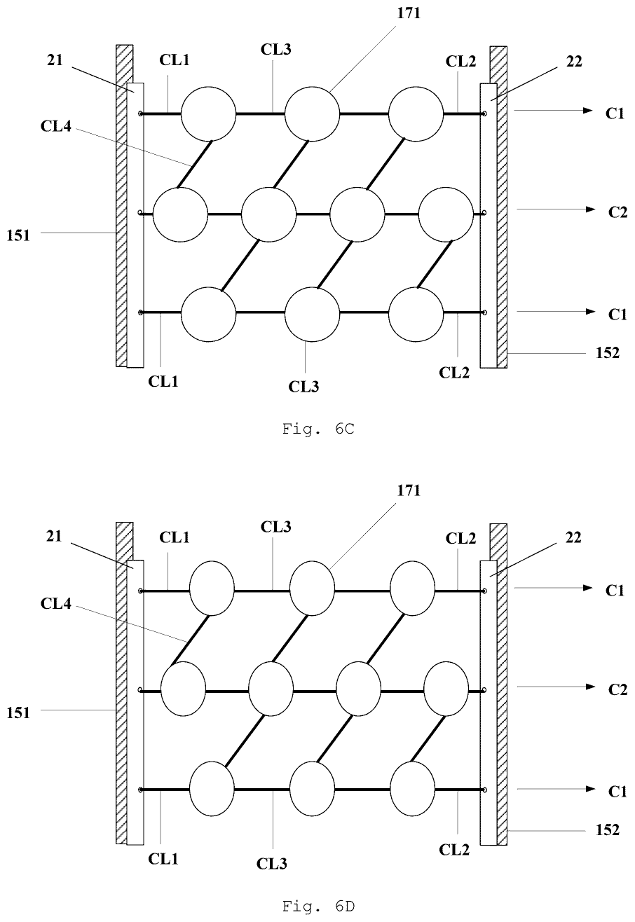

FIGS. 6A-6D are schematic views showing the distribution of a plurality of conductive parts according to some embodiments of the present disclosure. In FIGS. 6A and 6B, the shape of the conductive portion 171 is shown to be rectangular; in FIG. 6C, the shape of the conductive portion 171 is shown to be circular; in FIG. 6D, the shape of the conductive portion 171 is shown to be elliptical. It should be understood that the shape of the conductive portion 171 is not limited to these shapes, and in other embodiments, the shape of the conductive portion 171 may also be other shapes.

In some embodiments, the plurality of conductive portions 171 comprises a plurality of groups of conductive portions 171. Each group of conductive portions 171 are sequentially arranged along a direction from the first power portion 151 to the second power portion 152. FIG. 6A schematically shows three groups of conductive portions 171, wherein each row of conductive portions 171 are one group of conductive portions 171.

Adjacent conductive portions 171 in each group of conductive portions 171 are connected to each other via a third connection line CL3, a first conductive portion 171 in each group of conductive portions 171 that is closest to the first power portion 151 is connected to the first power portion 151 via a first connection line CL1, and a second conductive portion 171 in each group of conductive portions 171 that is closest to the second power portion 152 is connected to the second power portion 152 via a second connection line CL2. In this way, the plurality of groups of conductive portions 171 can shunt the current in the first power line 15 more effectively, to further reduce the possibility that the first power line 15 is burned during the aging process, and further improve the yield of the display panel.

In other embodiments, referring to FIGS. 6B to 6D, two adjacent groups of conductive portions 171 in the plurality of groups of conductive portions 171 comprise a first group of conductive portions C1 and a second group of conductive portions C2, and at least one conductive portion 171 of the first group of conductive portions C1 is connected to one conductive portion 171 of the second group of conductive portions C2 via a fourth connection line CL4. In this way, the plurality of groups of conductive portions 171 are cross connected to each other, which can shunt the current in the first power line 15 more effectively, thereby further reducing the possibility that the first power line 15 is burned during the aging process, and further improving the yield of the display panel.

In still some embodiments, different conductive portions 171 in the first group of conductive portions 171 are connected to different conductive portions 171 in the second group of conductive portions 171 via different fourth connection lines CL4. For example, one conductive portion 171 in the first group of conductive portions 171 is connected to one conductive portion 171 in the second group of conductive portions 171 via one fourth connection line CL4, and another conductive portion 171 in the first group of conductive portions 171 is connected to another conductive portion 171 in the second group of conductive portions 171 via another fourth connection line CL4. In this way, the plurality of conductive portions 171 form a mesh-like structure, which can shunt the current more effectively and is helpful to further reduce the possibility that the first power line 15 is burned during the aging process and further improve the yield of the display panel.

In some embodiments, one conductive portion 171 corresponds to one sub-pixel 13. For example, the overlapping portion of the orthographic projections of an anode 131 of a sub-pixel 13 corresponding to certain conductive portion 171 and a pixel opening exposing at least a part of this anode 131 on the base substrate 11 is located within the orthographic projection of this conductive portion 171 on the base substrate 11.

In some embodiments, a conductive portion 171 corresponding to certain type of sub-pixel in the first group of conductive portions 171 is connected to a conductive portion 171 corresponding to this type of sub-pixel in the second group of conductive portions 171 via the fourth connection line CL4. In other words, the conductive portions 171 corresponding to a same type of sub-pixel in different groups of conductive portions are connected via the fourth connection line CL4. For example, a conductive portion 171 corresponding to a red sub-pixel in the first group of conductive portions 171 is connected to a conductive portion 171 corresponding to a red sub-pixel in the second group of conductive portions 171 via the fourth connection line CL4.

In other embodiments, a conductive portion 171 corresponding to certain type of sub-pixel in the first group of conductive portions 171 is connected to a conductive portion 171 corresponding to another type of sub-pixel in the second group of conductive portions 171 via the fourth connection line CL4. In other words, the conductive portions 171 corresponding to different types of sub-pixels in different groups of conductive portions are connected via the fourth connection line CL4. For example, a conductive portion 171 corresponding to a red sub-pixel in the first group of conductive portions 171 is connected to a conductive portion 171 corresponding to a green sub-pixel in the second group of conductive portions 171 via the fourth connection line CL4.

In some embodiments, referring to FIGS. 6A to 6D, the display panel further comprises a first trace 21 located at the first peripheral region 112A and a second trace 22 located at the second peripheral region 112B. The first trace 21 is connected to the first power portion 151, and located in a different layer from the first power portion 151. The second trace 22 is connected to the second power portion 152, and located in a different layer from the second power portion 152. For example, the first trace 21 is in contact with the first power portion 151 (see FIG. 1C), and the second trace 22 is in contact with the second power portion 152.

At least one conductive portion 171, the first power portion 151 and the second power portion 152 are located in a same layer, and at least one conductive portion 171 is connected to the first trace 21 via the first connection line CL1, and at least one conductive portion 171 is connected to the second trace 22 via the second connection line CL2.

For example, the conductive portion 171 is connected to a first metal portion via a via hole, and the first metal portion is connected to the first trace 21 via a third trace. For another example, the conductive portion 171 is connected to a second metal portion via another via hole, and the second metal portion is connected to the first trace 21 via a fourth trace. The first metal portion, the second metal portion, the first trace 21, the second trace 22, the third trace and the fourth trace are all located in a same layer, for example, all located in a same layer as the first electrode E1.

In the above embodiments, the conductive portion 171 is connected to the first power portion 151 and the second power portion 152 via the first trace 21 and the second trace 22 respectively. In this way, the influence on other signal lines in a same layer where the conductive portion 171 and the first power portion 151 are located is avoided, and it is also convenient for the conductive portion 171 to be connected to the first power portion 151 and the second power portion 152 respectively.

The conductive portion 171 and the planarization portion 161 have been introduced above in conjunction with different embodiments. In some embodiments, the display panel comprises a conductive portion 171 and a planarization portion 161. In other embodiments, the display panel comprises one of the conductive portion 171 and the planarization portion 161. In some embodiments, the conductive portion 171 may function as the planarization portion 161; or the planarization portion 161 may function as the conductive portion 171.

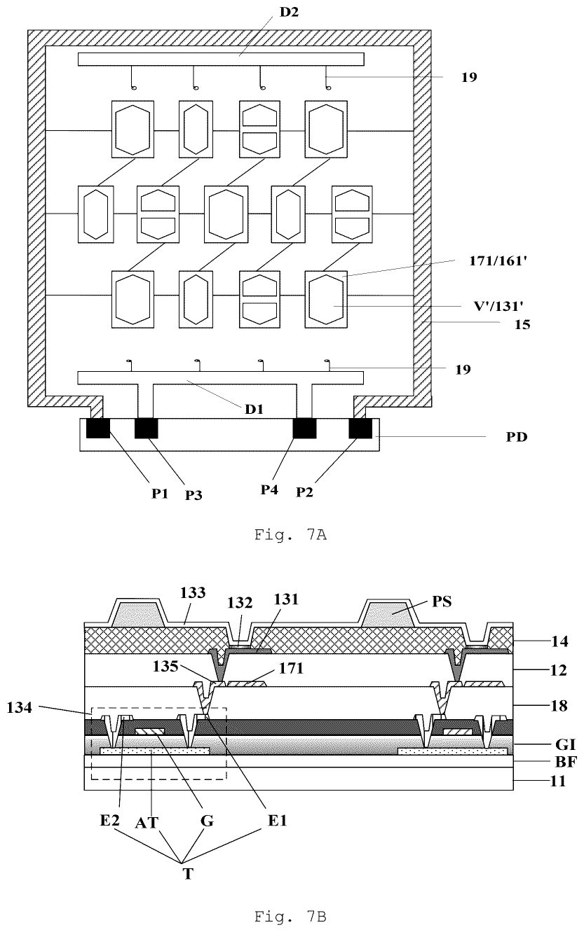

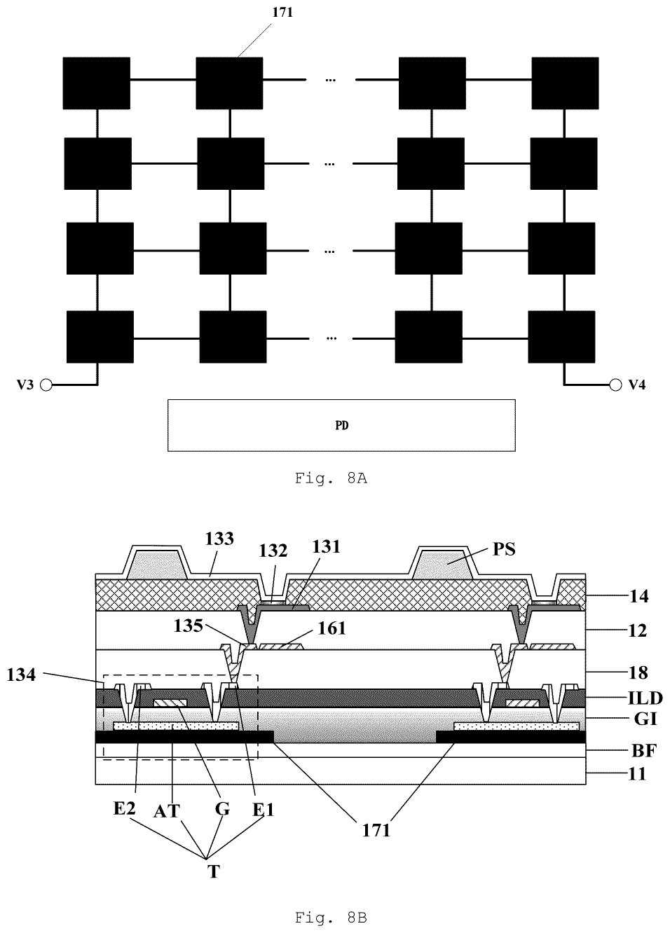

FIG. 7A is a schematic top view showing a display panel according to further embodiments of the present disclosure. FIG. 7B is a schematic top view showing a display region according to still other embodiments of the present disclosure.

In some embodiments, referring to FIGS. 7A and 7B, the display panel comprises a plurality of conductive portions 171 connected to each other, and each conductive portion 171 of the plurality of conductive portions 171 is reused as one of the plurality of planarization portions 161. In other words, the conductive portion 171 may function as the planarization portion 161. In this case, the orthographic projection of the conductive portion 171 on the base substrate 11 is a third orthographic projection 161′, and the overlapping portion of the first orthographic projection V′ of each pixel opening V in the first group of pixel openings V on the base substrate 11 and the second orthographic projection 131′ of a corresponding anode 131 of each pixel opening V in the first group of pixel openings V on the base substrate 11 is located within the third orthographic projection 161′ of the conductive portion 171 on the base substrate 11.

In the above embodiments, a plurality of conductive portions 171 is provided to reduce the possibility that the first power line 15 is burned during the aging process and improve the yield of the display panel on the one hand; and improve the flatness of a corresponding anode 131 and further alleviate the color cast problem of the display panel on the other hand.

In some embodiments, referring to FIG. 7A, one end of the data line 19 is connected to the pad region PD via a first connecting member D1 located at the peripheral region 112, and the other end of the data line 19 is connected to a second connecting member D2 located at the peripheral region 112. For example, the first connecting member D1 is connected to a plurality of pads in the pad region PD, for example, a third pad P3 and a fourth pad P4.

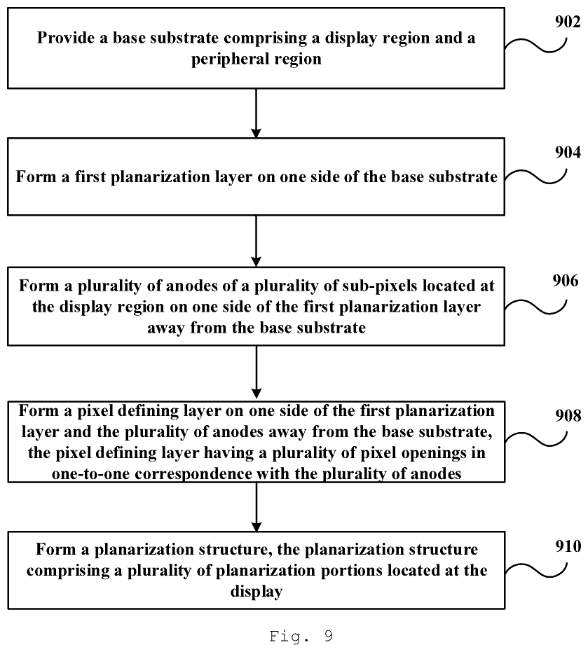

FIG. 8A is a schematic top view showing a display panel according to still other embodiments of the present disclosure. FIG. 8B is a schematic top view showing a display region according to still other embodiments of the present disclosure.

In some embodiments, the material of at least one conductive portion 171 in the display panel is light shielding material. As shown in FIG. 8A, the materials of a plurality of conductive portions 171 connected to each other are all light shielding materials. For example, one conductive portion 171 of the plurality of conductive portions is connected to the first power line 15 (for example, the first power portion 151) via a third via hole V3, and another conductive portion 171 of the plurality of conductive portions is connected to the first power line 15 (for example, the second power portion 152) via the fourth via hole V3.

Referring to FIG. 8B, each conductive portion 171 of at least one conductive portion 171 is located between the pixel driving circuit 134 of a corresponding sub-pixel 13 of the plurality of sub-pixels 13 and the base substrate 11. In addition, the orthographic projection of each conductive portion 171 on the base substrate 11 at least partially overlaps with the orthographic projection of the pixel driving circuit 134 of a corresponding sub-pixel 13 on the base substrate 11. For example, the orthographic projection of the pixel driving circuit 134 of a sub-pixel 13 on the base substrate 11 is located within the orthographic projection of a corresponding conductive portion 171 on the base substrate 11.

In the above embodiments, on the one hand, the conductive portion 171 can reduce the possibility that the first power line 15 is burned during the aging process and improve the yield of the display panel; and on the other hand, the conductive portion 171 may also produce the light shielding effect, thereby reducing the influence of light entering from one side of the base substrate 11 away from the pixel driving circuit 134 on the pixel driving circuit. In addition, the function of the conductive portion 1771 can be realized only with the light shielding layer in the display panel without additionally introducing other layers.

Some embodiments of that present disclosure also provide another display panel. The display panel comprises a base substrate 11, a plurality of sub-pixels 13, a first power line 15, and a conductive structure 17.

The base substrate 11, the plurality of sub-pixels 13 and the first power line 15 can refer to the above description, and thus will not be described in detail here. The conductive structure 17 comprises at least one conductive portion 171 located at the display region 111.

The conductive structure 17 will be described below in conjunction with different embodiments.

In some embodiments, at least one conductive portion 171 in the conductive structure 17 forms a current path with the first power line 15. With this structure, a part of the current flowing from the plurality of anodes 131 to the first power line 15 via the cathode 133 can flow in the current path formed by the conductive portion 171 and the first power line 15. In other words, a part of the current flowing from the plurality of anodes 131 to the first power line 15 via the cathode 133 can be shunted to the conductive portion 171. In this way, at least during the period when the part of the current that is shunted does not flow back to the first power line 15, the current flowing from the first power line 15 to the pad region PD is reduced, thereby reducing the possibility that the first power line 15 is burned during the aging process and improving the yield of the display panel.

In other embodiments, referring to FIGS. 2B and 2C, the at least one conductive portion 171 is connected to the first power line 15 via a first connection line CL1, and connected to the first power line 15 via a second connection line CL2. In other words, the at least one conductive portion 171 is connected to different positions of the first power line 15 via different connection lines. With this structure, a part of the current flowing from the plurality of anodes 131 to the first power line 15 via the cathode 133 can flow back to the first power line 15 via the first connection line CL1, the at least one conductive portion 171 and the second connection line CL2. In this way, at least during the period when the part of the current that is shunted does not flow back to the first power line 15, the current flowing from the first power line 15 to the pad region PD is reduced, thereby reducing the possibility that the first power line 15 is burned during the aging process and improving the yield of the display panel.

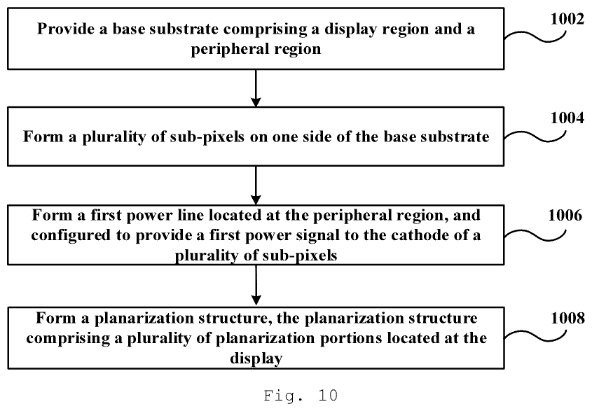

FIG. 9 is a flowchart showing a manufacturing method of a display panel according to some embodiments of the present disclosure.

It is to be noted that, steps 902 to 910 are not necessarily performed according to the sequence shown in FIG. 9. For example, certain member formed in one step and certain member formed in another step may be formed at the same time.

At step 902, a base substrate is provided. Here, the base substrate comprises a display region and a peripheral region. The base substrate may refer to the above description.

At step 904, a first planarization layer is formed on one side of the base substrate.

At step 906, a plurality of anodes of a plurality of sub-pixels located at the display region are formed on one side of the first planarization layer away from the base substrate.

For example, first, an anode material layer is formed on one side of the first planarization layer away from the base substrate, and then the anode material layer is patterned with a mask to form the plurality of anodes.

At step 908, a pixel defining layer is formed on one side of the first planarization layer and the plurality of anodes away from the base substrate, the pixel defining layer has a plurality of pixel openings in one-to-one correspondence with the plurality of anodes, and each pixel opening exposes at least a part of a corresponding anode.

For example, first, a pixel defining material layer is formed on one side of the first planarization layer and the plurality of anodes away from the base substrate, and then the pixel defining material layer is patterned with a mask to form a pixel defining layer comprising a plurality of pixel openings.

After the pixel defining layer is formed, a functional layer may also be formed in the pixel opening of the pixel defining layer. For example, functional layers of a red sub-pixel, a green sub-pixel and a blue sub-pixel are respectively formed by an evaporation process. After the functional layer is formed, a cathode is formed on one side of the functional layer away from the base substrate, and an encapsulation layer is further formed on one side of the cathode away from the base substrate.

At step 910, a planarization structure is formed.

The planarization structure comprises a plurality of planarization portions located at the display region. The plurality of planarization portions is located between the base substrate and the first planarization layer and covered by the first planarization layer, and the plurality of planarization portions is in one-to-one correspondence with a first group of pixel openings. The first group of pixel openings comprise at least a part of pixel openings of the plurality of pixel openings. The orthographic projection of each pixel opening of the first group of pixel openings on the base substrate is a first orthographic projection, the orthographic projections of a corresponding anode of each pixel opening of the first group of pixel openings and a corresponding planarization portion of each pixel opening of the first group of pixel openings on the base substrate are a second orthographic projection and a third orthographic projection respectively. The overlapping portion of the first orthographic projection and the second orthographic projection is located within the third orthographic projection.

FIG. 10 is a flowchart showing a manufacturing method of a display panel according to other embodiments of the present disclosure.

At step 1002, a base substrate is provided. Here, the base substrate comprises a display region and a peripheral region. The base substrate can refer to the above description.

At step 1004, a plurality of sub-pixels is formed on one side of the base substrate.

At step 1006, a first power line is formed. The first power line is located at the peripheral region and configured to provide a first power signal to the cathode of a plurality of sub-pixels.

At step 1008, a conductive structure is formed.

The conductive structure comprises at least one conductive portion located at the display region. In some embodiments, the at least one conductive portion is configured such that a part of the current flowing from the plurality of anodes to the first power line via the cathode flows back to the first power line via the at least one conductive portion. In other embodiments, the at least one conductive portion and the first power line form a current path. In still other embodiments, the at least one conductive portion is connected to the first power line via a first connection line, and connected to the first power line via a second connection line.

The display panel manufactured by the above embodiments comprises at least one of a planarization structure or a conductive structure. In this way, at least one of the color cast problem of the display panel or the problem that the first power line is burned during the aging process is alleviated, thereby improving the display effect of the display panel.

In some embodiments, a first electrode and a second electrode in a driving transistor of a sub-pixel, a portion of a data line (a first data portion) located at a display region, a first trace, a second trace, and a plurality of second power lines are formed by a same patterning process.

In some embodiments, a first power line, a plurality of planarization portions, a metal portion, and a portion of a data line (a first data portion) located at a peripheral region are formed by a same patterning process.

The present disclosure also provides a display device, which may comprise the display panel according to any some of the above embodiments. In some embodiments, the display device may be any product or member having a display function, such as a mobile terminal, a television, a display, a notebook computer, a digital photo frame, a navigator, or an electronic paper.

Hereto, various embodiments of the present disclosure have been described in detail. Some details well known in the art are not described to avoid obscuring the concept of the present disclosure. According to the above description, those skilled in the art would fully know how to implement the technical solutions disclosed herein.

Although some specific embodiments of the present disclosure have been described in detail by way of examples, those skilled in the art should understand that the above examples are only for the purpose of illustration and are not intended to limit the scope of the present disclosure. It should be understood by those skilled in the art that modifications to the above embodiments and equivalently substitution of part of the technical features can be made without departing from the scope and spirit of the present disclosure. The scope of the disclosure is defined by the following claims.

1. A display panel, comprising:
a base substrate comprising a display region and a peripheral region;
a first planarization layer located on one side of the base substrate;
a plurality of sub-pixels located at the display region, wherein a plurality of anodes of the plurality of sub-pixels is located on one side of the first planarization layer away from the base substrate;
a pixel defining layer located on one side of the first planarization layer and the plurality of anodes away from the base substrate, and having a plurality of pixel openings in one-to-one correspondence with the plurality of anodes, wherein each of the plurality of pixel openings exposes at least a part of an anode corresponding to each of the plurality of pixel openings; and
a planarization structure comprising a plurality of planarization portions located at the display region, the plurality of planarization portions being located between the base substrate and the first planarization layer and covered by the first planarization layer, and the plurality of planarization portions being in one-to-one correspondence with a first group of pixel openings, wherein the first group of pixel openings comprise at least a part of the plurality of pixel openings, an orthographic projection of each of the first group of pixel openings on the base substrate is a first orthographic projection, orthographic projections of an anode and a planarization portion which correspond to each of the first group of pixel openings on the base substrate are a second orthographic projection and a third orthographic projection respectively, and an overlapping portion of the first orthographic projection and the second orthographic projection is located within the third orthographic projection.

2. The display panel according to claim 1, further comprising:
a second planarization layer located between the first planarization layer and the base substrate, wherein the plurality of planarization portions is located between the first planarization layer and the second planarization layer;
wherein each of the plurality of sub-pixels further comprises:
a pixel driving circuit comprising a driving transistor, the driving transistor comprising a gate, a first electrode and a second electrode, wherein the first electrode and the second electrode are covered by the second planarization layer, and
a metal portion located between the first planarization layer and the second planarization layer, wherein the metal portion is connected to the anode via a first via hole penetrating through the first planarization layer and connected to the first electrode via a second via hole penetrating through the second planarization layer.

3. The display panel according to claim 2, wherein the plurality of planarization portions is located in a same layer as the metal portion.

4. The display panel according to claim 3, further comprising a plurality of data lines configured to provide a data signal to the plurality of sub-pixels, each of the plurality of data lines comprising:
a first data portion located at the display region and located in a same layer as the first electrode; and
a second data portion located at the peripheral region, connected to the first data portion and located in a same layer as the metal portion.

5. The display panel according to claim 3, further comprising:
a plurality of second power lines configured to provide a second power signal to the plurality of sub-pixels, wherein a voltage of the second power signal is greater than a voltage of a first power signal provided to a cathode of the plurality of sub-pixels, and the plurality of second power lines is located in a same layer as the first electrode.

6. The display panel according to claim 1, further comprising:
a plurality of signal lines configured to provide a signal to the plurality of sub-pixels,
wherein at least one planarization portion of the plurality of planarization portions is arranged in a same layer as one of the plurality of signal lines and connected to the one of the plurality of signal lines.

7. The display panel according to claim 6, wherein the plurality of signal lines extends along a first direction, and a minimum length of the at least one planarization portion in a second direction is greater than a maximum length of the one of the plurality of signal lines in the second direction, wherein the first direction is perpendicular to the second direction.

8. The display panel according to claim 6, wherein the plurality of signal lines comprises:
a data line configured to provide a data signal to the plurality of sub-pixels; or
a second power line configured to provide a second power signal to the plurality of sub-pixels, wherein a voltage of the second power signal is greater than a voltage of a first power signal provided to a cathode of the plurality of sub-pixels.

9. (canceled)

10. The display panel according to claim 1, wherein an area of the overlapping portion of the first orthogonal projection and the second orthogonal projection is smaller than an area of the third orthogonal projection.

11. The display panel according to claim 1, further comprising:
a first power line located at the peripheral region and configured to provide a first power signal to a cathode of the plurality of sub-pixels; and
a conductive structure comprising at least one conductive portion located at the display region, wherein the at least one conductive portion is configured such that a part of current flowing from the plurality of anodes to the first power line via the cathode flows back to the first power line via the at least one conductive portion.

12. A display panel, comprising:
a base substrate comprising a display region and a peripheral region;
a plurality of sub-pixels located at the display region;
a first power line located at the peripheral region and configured to provide a first power signal to a cathode of the plurality of sub-pixels; and
a conductive structure comprising at least one conductive portion located at the display region, wherein the at least one conductive portion is configured such that a part of current flowing from a plurality of anodes of the plurality of sub-pixels to the first power line via the cathode flows back to the first power line via the at least one conductive portion.

13. The display panel according to claim 12, wherein:
the peripheral region comprises a first peripheral region and a second peripheral region arranged oppositely, and a third peripheral region and a fourth peripheral region arranged oppositely, wherein the third peripheral region and the fourth peripheral region are both adjacent to the first peripheral region and the second peripheral region;
the first power line comprises: a first power portion located at the first peripheral region; a second power portion located at the second peripheral region; a third power portion located at the third peripheral region and connected between the first power portion and the second power portion; and a fourth power portion located at the fourth peripheral region and comprising a first portion and a second portion, wherein the first portion is connected between the first power portion and a first pad, and the second portion is connected between the third power portion and a second pad; and
the at least one conductive portion is connected to the first power portion via a first connection line and connected to the second power portion via a second connection line.

14. The display panel according to claim 13, wherein the at least one conductive portion comprises a plurality of conductive portions connected to each other.

15. The display panel according to claim 14, wherein the plurality of conductive portions comprises a plurality of groups of conductive portions, wherein each group of conductive portions are arranged sequentially along a direction from the first power portion to the second power portion, adjacent conductive portions in each group of conductive portions are connected to each other via a third connection line, a first conductive portion in each group of conductive portions that is closest to the first power portion is connected to the first power portion via the first connection line, and a second conductive portion in each group of conductive portions that is closest to the second power portion is connected to the second power line via the second connection line.

16. The display panel according to claim 15, wherein two adjacent groups of conductive portions of the plurality groups of conductive portions comprise a first group of conductive portions and a second group of conductive portions, and at least one conductive portion of the first group of conductive portions is connected to one conductive portion of the second group of conductive portions via a fourth connection line, wherein different conductive portions in the first group of conductive portions are connected to different conductive portions in the second group of conductive portions via different fourth connection lines.

17. (canceled)

18. The display panel according to claim 13, further comprising:
a first trace located at the first peripheral region, connected to the first power portion, and located in a different layer from the first power portion; and
a second trace located at the second peripheral region, connected to the second power portion, and located in a different layer from the second power portion,
wherein the at least one conductive portion, the first power portion and the second power portion are located in a same layer, and the at least one conductive portion is connected to the first trace via the first connection line and connected to the second trace via the second connection line.

19. (canceled)

20. The display panel according to any claim 11, wherein the at least one conductive portion comprises a plurality of conductive portions connected to each other, and each of the plurality of conductive portions is reused as one of the plurality of planarization portions.

21. The display panel according to claim 11, wherein a material of the at least one conductive portion is light shielding material, each of the at least one conductive portion is located between a pixel driving circuit of a corresponding sub-pixel of the plurality of sub-pixels and the base substrate, and an orthographic projection of each of the at least one conductive portion on the base substrate at least partially overlaps with an orthographic projection of the pixel driving circuit of the corresponding sub-pixel on the base substrate.

22. A display panel, comprising:
a base substrate comprising a display region and a peripheral region;
a plurality of sub-pixels located at the display region;
a first power line located at the peripheral region and configured to provide a first power signal to a cathode of the plurality of sub-pixels; and
a conductive structure comprising at least one conductive portion located at the display region, wherein the at least one conductive portion is connected to the first power line via a first connection line and connected to the first power line via a second connection line.

23. A display device, comprising the display panel according to claim 1.

24. (canceled)

25. (canceled)
